(19) United States
(12) Patent Application Publication
(10) Pub. No.: US 2006/0114128 A1
(43) Pub. Date: Jun. 1, 2006

(54) Operating device for a domestic electrical appliance

(75) Inventors: Michael Prinz, Leutkirch (DE); Stefan Hoss, Leutkirch (DE); Roland Sohler, Christazhofen (DE)

Correspondence Address: LERNER GREENBERG STEMER LLP, P O BOX 2480, HOLLYWOOD, FL, 33022-2480, US

(73) Assignee: Diehl AKO Stiftung & Co. KG

(21) Appl. No.: 11/284,588

(22) Filed: Nov. 22, 2005

(30) Foreign Application Priority Data
Nov. 30, 2004 (DE) 10 2004 057 553.3
Apr. 1, 2005 (DE) 10 2005 014 935.9

(51) Int. Cl. H03M 11/00; G05B 11/01; G09G 5/00

(52) U.S. Cl. 341/22; 700/17; 345/156

(57) ABSTRACT

An operating device for a domestic electrical appliance such as a dishwasher or an electric oven, contains a control device, a plurality of electrical operating, switching and/or display elements which and a plurality of mechanical actuating elements and/or optical display elements which can be operated or observed respectively by a user and which are respectively associated with the electrical operating, switching and/or display elements. A carrier is provided for holding the plurality of actuating elements and/or optical display elements. The plurality of mechanical actuating elements and/or optical display elements and the carrier form an integral functional module. The carrier is formed from at least one hard component and the plurality of mechanical actuating elements and/or optical display elements are formed from at least one soft component, thus affording a reduced number of component elements for the operating device, which leads to advantages in regard to storage and assembly.

### BACKGROUND OF THE INVENTION

1. Field of the Invention

The present invention relates to an operating device for a domestic electrical appliance such as for example a dishwasher, a washing machine, an electric cooker, a microwave oven or the like.

An operating device of this kind is known for example from German Utility Model DE 200 02 947 U1. The operating device serves as an interface between a user and a control configuration of the domestic appliance. The operating device includes a circuit board on which there are various electrical operating, switching and/or display elements coupled to the control configuration, a plurality of mechanical actuating elements in the form for example of pushbutton switches or rotary controls, and optical display elements in the form for example of seven-segment displays which are respectively associated with the electrical operating, switching and/or display elements on the circuit board by pushrods, light guides and so forth. A carrier is provided for holding the mechanical actuating elements and optical display elements, and a decorative trim panel is placed on the side of the carrier, and it faces towards the user.

A further operating device of this kind is described in German patent DE 102 58 563 B3, corresponding to U.S. patent publication No. 2004/0230321 A1. In the known operating device the plurality of electrical operating, switching and/or display elements, the plurality of mechanical actuating elements and/or optical display elements, and the carrier, are provided in the form of a functional unit which is disposed according to the design involved at the front side which is towards the user, so that the decorative panel has a single large opening for the functional unit.

What is common to the conventional operating devices is that they have a large number of individual components which, depending on the respective size and configuration thereof, are in part very difficult to fit so that the assembly costs of such operating devices are relatively high.

2. Summary of the Invention

It is accordingly an object of the invention to provide an operating device for a domestic electrical appliance which overcomes the above-mentioned disadvantages of the prior art devices of this general type, which has a smaller number of components so that assembly is simplified and the assembly costs are reduced.

The operating device for the domestic electrical appliance includes a control device, a plurality of electrical operating, switching and/or display elements which are coupled to the control device, and a plurality of mechanical actuating elements and/or optical display elements which can be operated or observed respectively by a user and which are respectively associated with the electrical operating, switching and/or display elements. A carrier is provided for holding the plurality of actuating elements and/or optical display elements. According to the invention the plurality of mechanical actuating elements and/or optical display elements and the carrier are in the form of an integral functional module. The carrier is formed from at least one hard component and the plurality of mechanical actuating elements and/or optical display elements are formed from at least one soft component.

In contrast to conventional operating devices therefore there are not a carrier and a large number of mechanical actuating elements and/or optical display elements which have to be assembled, but only the one integral functional module. In comparison with the somewhat higher production costs of the integral functional module, by virtue of the at least two material components, there are marked savings in complication and cost in terms of storage and assembly.

The mechanical actuating elements of the functional module include for example pushbutton switches, and the optical display elements of the functional module include for example operating displays, function displays, seven-segment displays and/or symbol displays.

In a further configuration of the invention the mechanical actuating elements of the functional module are respectively provided with decorative caps on the side towards the user, the caps preferably formed of the hard component and being integral with the functional module. That affords a further reduction in the components and the assembly costs in comparison with conventional operating devices with such decorative caps.

In addition it is possible to provide on the side of the functional module that faces towards the user a decorative panel with corresponding openings for the mechanical actuating elements and/or optical display elements. Alternatively the functional module itself is provided with a decorative design on the side that faces towards the user so that a separate decorative panel can be omitted, which results in a further simplification in assembly and cost savings.

In a further configuration of the invention the functional module is further provided with a seal for example at its side that is remote from the user and/or in the edge region in order to seal off the electronic components of the operating device. The seal is preferably also made from a soft component and integral with the functional module, thus affording a further simplification in regard to assembly and storage of the operating device.

In a configuration of the invention the plurality of electrical operating, switching and/or display elements of the operating device are arranged in a casing and the functional module is connected to the casing.

In still a further configuration of the invention the functional module is further provided with a damping element for mechanical damping or buffering between the functional module and an adjacent component (for example the decorative panel or casing) of the operating device. The damping element is preferably also made from a soft component and is integral with the functional module, thus affording a further simplification in regard to assembly and storage of the operating device.

In a preferred embodiment of the invention the carrier and the plurality of mechanical actuating elements and/or optical display elements are formed by integral injection molding. In that respect the at least one hard component is a casing plastic material such as for example ABS, PA, PA66, PBT, PCABS or the like, and the at least one soft component is a thermoplastic or a thermosetting elastomer.

Other features which are considered as characteristic for the invention are set forth in the appended claims.

Although the invention is illustrated and described herein as embodied in an operating device for a domestic electrical appliance, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, cross-sectional view of a conventional operating device;

FIG. 2 is a diagrammatic, top perspective view of a preferred embodiment by way of example of a functional module of an operating device according to the invention;

FIG. 3 is a diagrammatic, perspective view of an embodiment of a part of the functional module shown in FIG. 2, in the form of a soft component;

FIG. 4A is a diagrammatic, perspective view of an embodiment of a first part of the functional module shown in FIG. 2, in the form of a hard component;

FIG. 4B is a diagrammatic, perspective view of an embodiment of a second part of the functional module shown in FIG. 2, in the form of a hard component;

FIG. 4C is a diagrammatic, side view of an embodiment of a reinforcing element of the part in the form of a hard component shown in FIG. 4A; and

FIG. 5 is a diagrammatic, bottom perspective view of the functional module shown in FIG. 2.

### DESCRIPTION OF THE PREFERRED EMBODIMENTS

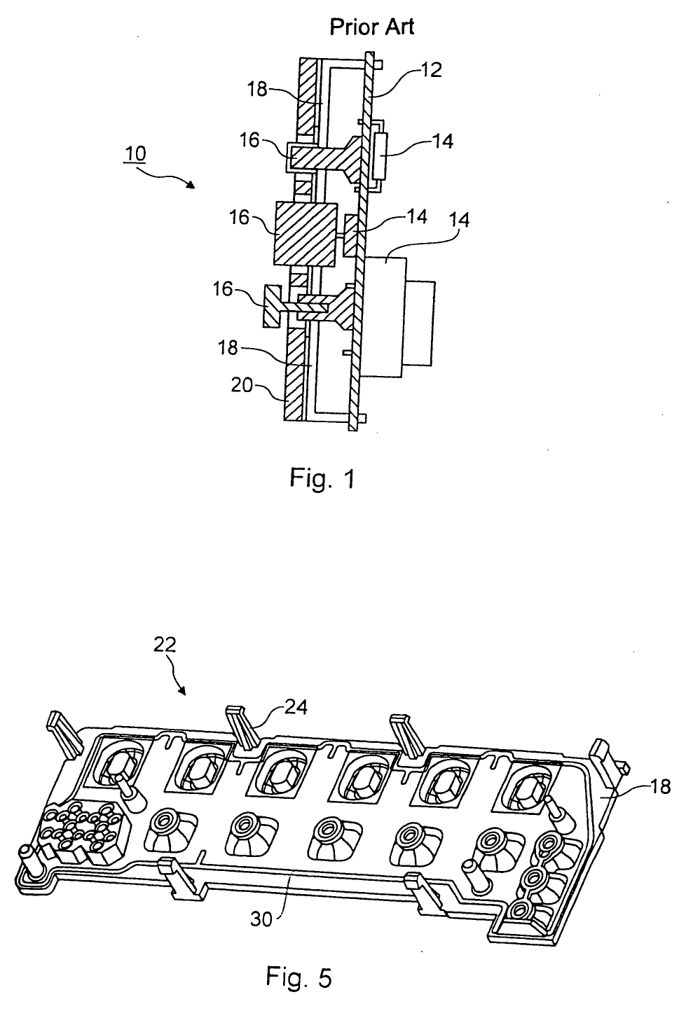

Referring now to the figures of the drawing in detail and first, particularly, to FIG. 1 thereof, there is shown a prior art operating device 10 which serves as an interface between a user and a non-illustrated control configuration of the domestic appliance. The operating device 10 includes a circuit board 12 on which there are various electrical operating, switching and/or display elements 14 coupled to the non-illustrated control configuration. A plurality of mechanical actuating elements 16 in the form for example of pushbutton switches or rotary controls, and non-illustrated optical display elements in the form for example of seven-segment displays which are respectively associated with the electrical operating, switching and/or display elements 14 on the circuit board 12 by pushrods, light guides and so forth. A carrier 18 is provided for holding the mechanical actuating elements 16 and optical display elements. A decorative trim panel 20 is placed on the side of the carrier 18 that faces towards the user.

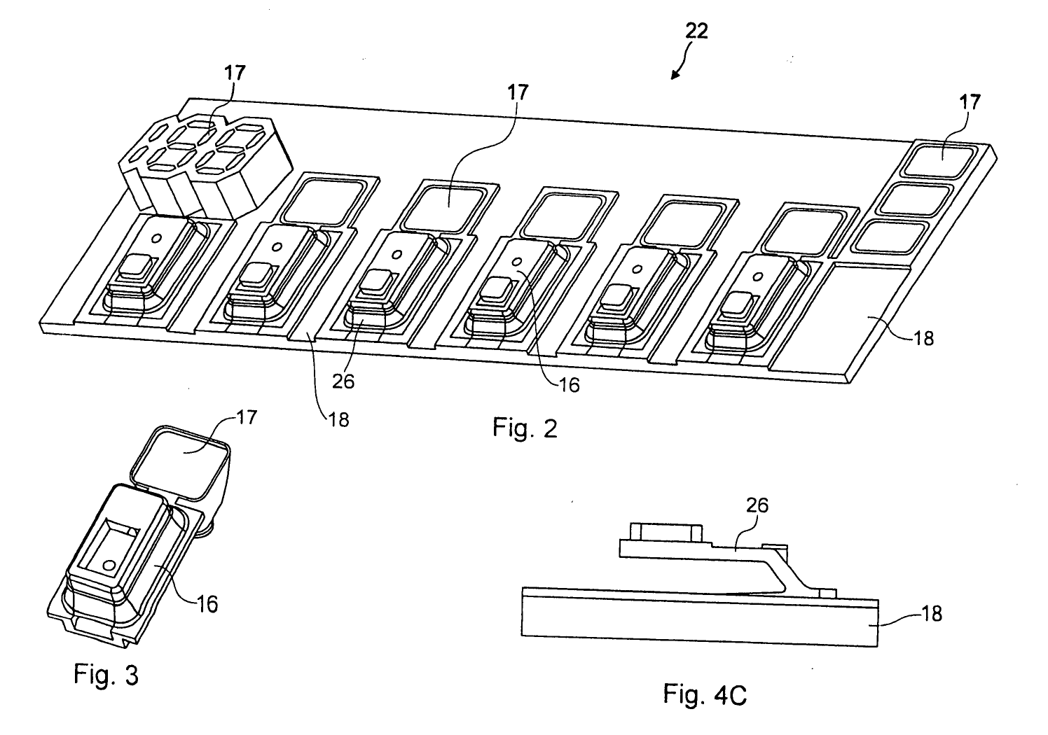

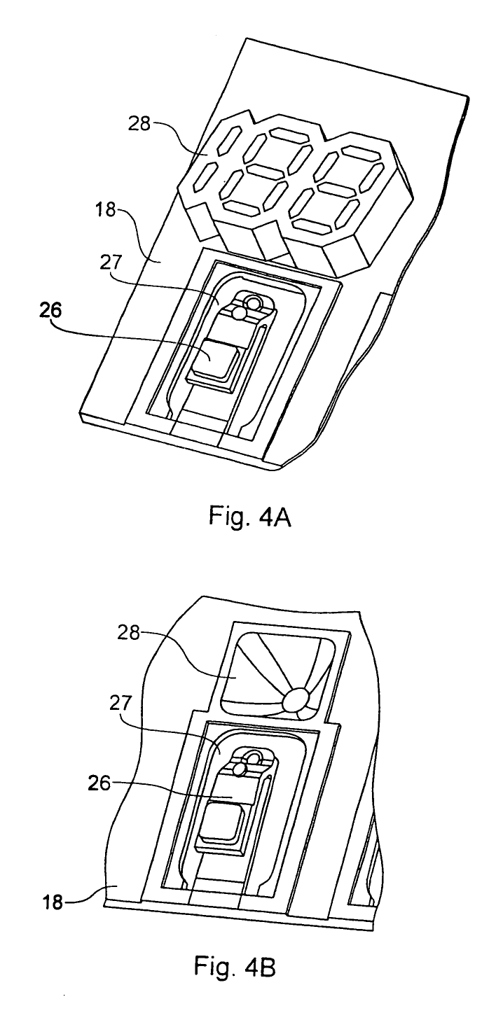

Turning now to FIGS. 2-5, there is shown a preferred embodiment of a functional module for an operating device according to the invention. In this respect FIGS. 2 and 5 each show a perspective view of the entire functional module while FIGS. 3-4C show individual parts of the functional module in greater detail.

An integral functional module 22 shown in FIGS. 2 to 5 can be used in the operating device 10 for a domestic electrical appliance, the structure of the operating device 10 corresponding for example to that shown in FIG. 1. In that respect the operating device 10 can be used for example for dishwashers, washing machines, electric cookers, microwave ovens and the like.

The integral functional module 22 in FIGS. 2 to 5 combines the components 16-18 of the operating device 10 in FIG. 1 in one structural part, so that a marked reduction in the component parts is achieved, which results in easier and less expensive assembly and storage of the operating device.

In particular the integral functional module 22 has the carrier 18 formed from a hard (material) component. As shown in FIGS. 4A and 4B, the carrier 18 has a plurality of openings 27 for mechanical actuating elements 16 and a plurality of openings 28 for optical display elements 17. Arranged in those openings 27, 28 are the corresponding mechanical actuating elements 16 and the optical display elements 17 that are formed from at least one soft (material) component.

In the present embodiment the functional module 22 includes a total of six mechanical actuating elements 16 which are in the form of pushbutton switches, an optical display element 17 in the form of a seven-segment display, five optical display elements 17 which are in the form of operating displays and which are each associated with a respective pushbutton switch 16, and three optical display elements 17 in the form of functional or symbol displays. It will be appreciated however that the present invention is not just limited to that specific embodiment by way of example. In particular, functional modules 22 with a different number and/or arrangement of mechanical actuating elements 16, with a different number and/or arrangement of optical display elements 17, exclusively with mechanical actuating elements 16, exclusively with optical display elements 17, with different kinds and/or sizes of mechanical actuating elements 16, with different kinds and/or sizes of optical display elements 17, and the like, can be used in accordance with the present invention in the operating device 10 for a domestic electrical appliance.

The optical display elements 17 formed of the soft component each form a respective light guide or a reflector field for guiding the radiation from an electrical display element 14 on the circuit board 12 to the side of the operating device 10, which is towards the user, and can also be combined with diffusing covers or symbol representations. The mechanical actuating elements 16 serve for mechanical actuation of an electrical operating or switching element 14 on the circuit board 12 with or without the interposition of a pushrod. The actuating elements 16 which are in the form of pushbutton switches are preferably of an elastic nature with a return force. If the return force afforded by the material and the structure of the actuating element 16 is not sufficient, it is optionally possible to provide an additional reinforcing element 26 (see FIG. 4C) which is formed integrally with the carrier 18 of the hard component and which assists with the return of the actuating element 16 of the soft component into its starting position.

The integral functional module 22 is preferably produced by injection moulding. In that case, first the carrier 18 formed as or containing the hard component is injection molded, and then the mechanical actuating elements 16 and the optical display elements 17 formed of or containing the at least one soft component are injection molded in the carrier 18 which is already provided, thus forming an integral composite of the hard and soft components. As is known that composite can be reinforced by mechanical anchorage devices between the two material components. The integral functional module 22 containing at least two different material components can be rationally manufactured in that way.

Preferably only one soft component is used both for the mechanical actuating elements 16 and also for the optical display elements 17 of the functional module 22, as that simplifies and reduces the cost of manufacture. For that purpose, a compromise must be made between the light guide properties and the mechanical properties of the soft component. In accordance with the present invention however it is equally possible to use a plurality of different soft (material) components and also a plurality of different hard (material) components, which admittedly increases the production costs but on the other hand allows optimum adaptation to the various functional regions of the functional module 22.

Various variants of the functional module 22 with different optical display elements 17 and mechanical actuating elements 16 can be embodied in a simple manner in the injection molding operation by interchangeable inserts in the variable region.

Insofar as only one soft component is used in each case for the various functional components of the functional module 22, preferably only one respective injection point can be used for the three optical display elements 17 at top right in FIG. 2 and for the five mutually associated pushbutton switches 16 and light guides 17 (see FIG. 3).

The hard component for the carrier 18 is preferably a casing plastic material such as for example ABS, PA, PA66, PBT, PCABS and so forth. The soft component for the mechanical actuating elements 16 and the optical display elements 17 are for example thermoplastic elastomers based on polyethylene, polyurethane, polypropylene and the like or thermosetting elastomers such as for example a self-adhering liquid silicone with a platinum catalyst for full vulcanization.

For easy assembly of the functional module 22 it has for example at its side remote from the user a plurality of latching hooks 24 as shown in FIG. 5 which can come into snapping engagement in corresponding openings on a non-illustrated casing for the electronic components of the operating device 10. The latching hooks 24 are preferably made from a hard component and are integral with the carrier 18 of the functional module 22.

It is also conceivable in this connection for the carrier 18 of the functional module 22 to form a first casing portion which is connected by way of a film hinge, preferably containing a soft component, to a second casing portion containing a hard component. After the circuit board 12 with the electrical operating, switching and/or display elements 14 is fitted into the second casing portion the functional module 22 can be fitted as a cover on to the second casing portion and the electronic components of the operating device 10 are thus integrated into a casing. The circuit board 12 is connected to the control device of the domestic appliance for example by way of a suitable plug connection on the second casing portion. The two casing portions and the film hinge are preferably integrally injection moulded.

As is also shown in FIG. 5 the functional module 22 can also be provided at its side remote from the user with a seal 30 which is intended to seal off the electrical components of the operating device 10, in particular in relation to fluids. With the configuration of the functional module 22 according to the invention, the seal 30 can also be made from a soft component which is also provided integrally with the functional module 22.

Although not illustrated, the integral functional module 22 of the operating device 10 according to the invention can further have at least one damping or buffer element which is intended to provide in particular mechanical damping of the functional module 22 with respect to adjacent components of the operating device 10 such as for example the decorative panel 20 or the casing of the electronic components. The damping element is preferably also made from a soft component which is also produced integrally with the functional module 22.

The seal 30 and the damping element can also be made from a softer soft component than the mechanical actuating elements 16 and the optical display elements 17.

The mechanical actuating elements 16 of the functional module 22 can also be provided with decorative caps on the side towards the user. Those decorative caps are preferably formed from a hard component and can therefore advantageously also be produced integrally with the functional module 22, if desired.

In addition, the operating devices 10 are usually provided on the side that faces towards the user with a decorative trim panel 20 which includes appropriate openings for the mechanical actuating elements 16 and the optical display elements 17 of the operating device 10. In the case of the operating device 10 according to the invention, it is possible in this connection for the side of the integral functional module 22, that faces towards the user, to be provided with a decorative design so that the decorative panel can be omitted in that region and only has to have a frame with a single large opening. Such a structure for the operating device 10 is possible in particular also for the reason that the functional module 22 can also have excellent insulating properties by virtue of a suitable choice of the material components. That structure for an operating device 10 is already disclosed in a similar manner in DE 102 58 563 B3 to the present applicants.

As described above, the operating device 10 of the invention is distinguished by an integral functional module 22 which can combine a plurality of component parts and functions of the operating device such as for example optical display elements, mechanical actuating elements, seals, damping elements and the like, by way of a carrier. As an integral component part the assembly procedure is substantially simplified in comparison with conventional operating devices with a plurality of individual component elements.

This application claims the priority, under 35 U.S.C. § 119, of German patent application No. 10 2004 057 553.3, filed Nov. 30, 2004 and German patent application No. 10 2005 014 935.9, filed Apr. 1, 2005; the entire disclosure of the prior applications is herewith incorporated by reference.

We claim:

1. An operating device for a domestic electrical appliance, the operating device comprising:
a control device;
a plurality of electrical elements containing at least one element selected from the group consisting of operating elements, switching elements and display elements coupled to said control device;
a plurality of further elements containing at least one further element selected from the group consisting of mechanical actuating elements and optical display elements which can be operated or observed respectively by a user and respectively associated with said electrical elements; and
a carrier for holding said plurality of further elements, said plurality of further elements and said carrier forming an integral functional module, said carrier formed from at least one hard component material and said plurality of further elements formed from at least one soft component material being softer than said hard component material.

2. The operating device according to claim 1, wherein said mechanical actuating elements of said integral functional module include pushbutton switches.

3. The operating device according to claim 1, wherein said optical display elements of said integral functional module include at least one element selected from the group consisting of operating displays, function displays, seven-segment displays and symbol displays.

4. The operating device according to claim 1, wherein said mechanical actuating elements of said integral functional module each have decorative caps on sides facing towards the user.

5. The operating device according to claim 4, wherein said decorative caps of said mechanical actuating elements of said integral functional module are made from said hard component material and are integral with said integral functional module.

6. The operating device according to claim 1, wherein said integral functional module has a side facing towards the user, said side having a decorative panel with corresponding openings formed therein for receiving said mechanical actuating elements and/or said optical display elements.

7. The operating device according to claim 1, wherein said integral functional module has a decorative design on a side facing toward the user.

8. The operating device according to claim 1, wherein said integral functional module has a seal for sealing off electronic components of the operating device.

9. The operating device according to claim 8, wherein said seal of said integral functional module is formed of said soft component material and is integral with said integral functional module.

10. The operating device according to claim 1, further comprising a casing, said plurality of electrical elements being disposed in said casing and said integral functional module is connected to said casing.

11. The operating device according to claim 1, wherein said integral functional module has a damping element for damping between said integral functional module and an adjacent component of the operating device.

12. The operating device according to claim 11, wherein said damping element is formed of said soft component material and is integral with said integral functional module.

13. The operating device according to claim 1, wherein said carrier and said plurality of further elements are formed by integral injection molding.

14. The operating device according to claim 1, wherein said at least one hard component material is a casing plastic material selected from the group consisting of ABS, PA, PA66, PBT, and PCABS.

15. The operating device according to claim 1, wherein said at least one soft component material is a thermoplastic or a thermosetting elastomer.
